(19) United States
(12) Patent Application Publication
(10) Pub. No.: US 2008/0157388 A1
(43) Pub. Date: Jul. 3, 2008

(54) Semiconductor Device and Fabricating Method Thereof

(76) Inventor: JAE WON HAN, Soowon-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/932,609

(22) Filed: Oct. 31, 2007

(30) Foreign Application Priority Data
Dec. 27, 2006 (KR) 10-2006-0135747

(51) Int. Cl. H01L 23/52; H01L 21/4763

(52) U.S. Cl. 257/773; 438/618; 257/E23.141; 257/E21.495

(57) ABSTRACT

A semiconductor device and fabricating method thereof are provided. A semiconductor substrate includes at least two holes for receiving devices, and at least two devices are inserted into the holes of the semiconductor substrate. Connection electrodes electrically connect the devices with each other, and the bonding pad portion provides signal connection between the connected devices and an outside device.

### CROSS-REFERENCE TO RELATED APPLICATIONS

The present application claims the benefit under 35 U.S.C §119 of Korean Patent Application No. 10-2006-0135747, filed Dec. 27, 2006, which is hereby incorporated by reference in its entirety.

### BACKGROUND

As semiconductor integrated circuit technology has become more developed, research has focused on system on a chip (SoC) technology of integrating analog circuits, radio frequency chips, central processing units, and complementary metal oxide semiconductor (CMOS) sensors into one chip. However, it has proven to be very difficult to integrate many different kinds of devices having different design rules into one chip.

A system in a package (SiP) design can provide an integrated circuit (IC) with a high degree of integration by incorporating different parts or ICs into one package. However, it can be very difficult to fabricate a through electrode and heat sink of an interlayer device, and to achieve noise removal between electrodes in a package.

A current common method involves fabricating individual unit devices and then integrating the individual unit devices on a printed circuit board (PCB) substrate through sawing and wire bonding.

When using this method, though, there is a limit in how integrated a circuit can be because a large amount of space is often used. Additionally, noise at wire bonding and interconnection of the PCB substrate typically occurs.

Thus, there exists a need in the art for an improved semiconductor integrated circuit and fabricating method thereof.

### BRIEF SUMMARY

Embodiments of the present invention provide a semiconductor device and a fabricating method thereof. The fabricating process can be simplified, efficiency can be improved, and a high degree of integration can be achieved.

In an embodiment, a semiconductor device can include: a semiconductor substrate including at least two holes; a plurality of devices inserted into the holes of the semiconductor substrate; at least one connection electrode for electrically connecting the plurality of devices with each other; and a bonding pad portion for signal connection between the plurality of connected devices and an outside device.

A method for fabricating a semiconductor device according to an embodiment can include providing a semiconductor substrate including at least two holes and inserting a plurality of devices into the holes of the semiconductor substrate. Connection electrodes for electrically connecting the plurality of devices with each other can be formed, and a bonding pad portion can also be formed for signal connection between the plurality of connected devices and an outside device.

### BRIEF DESCRIPTION OF THE DRAWINGS

FIG. 1 is a top view of a system by interconnection (SbI) according to an embodiment of the present invention.

FIG. 2 is a cross-sectional view of a SbI according to an embodiment of the present invention.

FIG. 3 is a cross-sectional view of a SbI according to an embodiment of the present invention.

### DETAILED DESCRIPTION

When the terms “on” or “over” are used herein, when referring to layers, regions, patterns, or structures, it is understood that the layer, region, pattern or structure can be directly on another layer or structure, or intervening layers, regions, patterns, or structures may also be present. When the terms “under” or “below” are used herein, when referring to layers, regions, patterns, or structures, it is understood that the layer, region, pattern or structure can be directly under the other layer or structure, or intervening layers, regions, patterns, or structures may also be present.

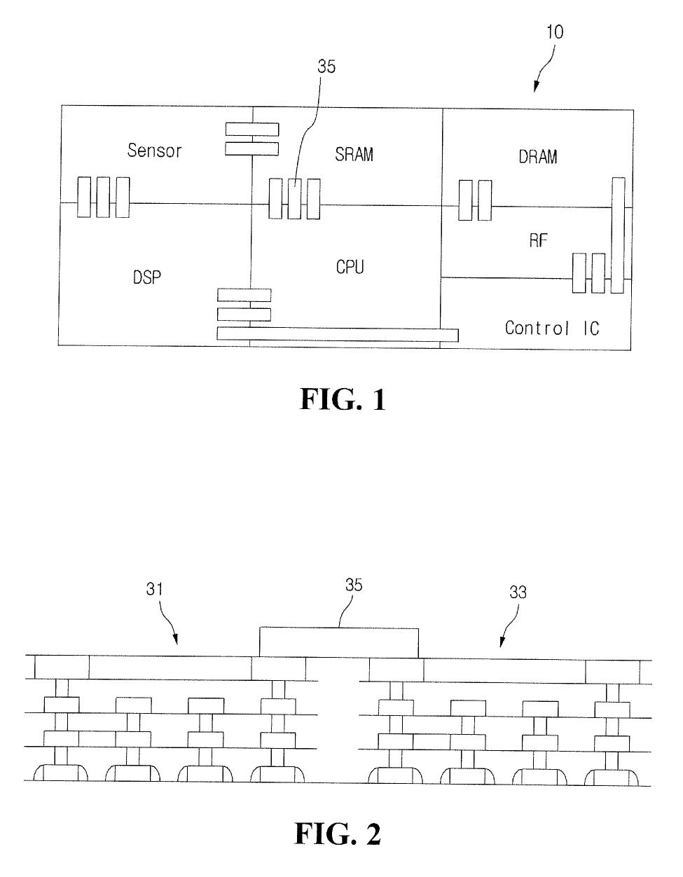

System by interconnection (SbI) refers to a method in which unit devices are interconnected. The unit devices can be any device used in the art in a semiconductor device, for example, central processing units (CPUs), static random access memories (SRAMs), dynamic random access memories (DRAMs), flash memories, logic devices, power integrated circuits (ICs), control ICs, and sensor chips. Referring to FIGS. 1 and 2, the unit devices can be interconnected with each other using connection electrodes 35 to form an integrated device 10.

In an embodiment, SbI can include fabricating a semiconductor device by first fabricating a first device 31 and a second device 33 on separate semiconductor substrates, and then electrically connecting the first device 31 to the second device 33 via the connection electrode 35.

In an embodiment, a method is provided that can efficiently integrate individual unit devices using SbI.

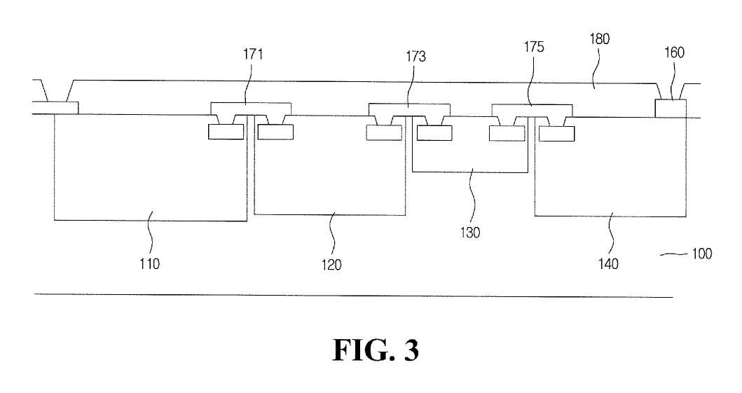

Referring to FIG. 3, a semiconductor device according to an embodiment can include a semiconductor substrate 100 including at least two holes for receiving devices, and at least two devices (for example, a first device 110, a second device 120, a third device 130, and a fourth device 140) inserted into the holes of the semiconductor substrate 100. The semiconductor device can also include at least one connection electrode (for example, connection electrodes 171, 173, and 175) for electrically connecting the devices (for example, the first, second, third, and fourth devices 110, 120, 130, and 140). A bonding pad portion 160 can also be provided for signal connection between the devices (for example, the first, second, third, and fourth devices 110, 120, 130, and 140) and an outside device. Though four devices have been shown in FIG. 3 for purposes of illustration, any suitable number of devices greater than one can be used in a semiconductor device according to embodiments of the present invention.

In an embodiment, the semiconductor substrate 100 can be formed of a silicon wafer. Holes for receiving unit devices can be formed in the silicon wafer semiconductor substrate 100 through an etching process. During an etching process, holes can be formed to appropriate depths for the devices that will be inserted by controlling etching depths.

The devices (for example, the first, second, third, and fourth devices 110, 120, 130, and 140) that can be inserted into the holes of the semiconductor substrate 100 can be individual devices manufactured from separate wafers. Each device (for example, the first, second, third, and fourth devices 110, 120, 130, and 140) can be, independently, an image sensor, a device having a capacitor cell, a device having an inductor cell, a CPU, SRAM, DRAM, flash memory, a logic device, a power IC, a control IC, a sensor chip, or any other appropriate device known in the art.

In an embodiment, each device (for example, the first to fourth devices 110, 120, 130, and 140) to be inserted into the holes of the semiconductor substrate 100 can be formed to have the same height.

In a further embodiment, a passivation layer 180 can be formed on the connection electrodes (for example, 171, 173, and 175). Each connection electrodes 171, 173, and 175 can be a metal layer. Any suitable material known in the art can be used for the metal layers, for example, Al, Ti/TiN/Al/Ti/TiN, Ti/Al/Ti/TiN, Ti/Al/TiN, Ti/TiN/Al/Ti, Ti/TiN/Al/TiN, Cu, TaN/Cu/TaN, or any combination thereof. The metal layers can be formed to have a thickness of about 100 Å to about 10,000 Å. The metal layer can be formed using physical vapor deposition (PVD), chemical vapor deposition (CVD), or any other appropriate method known in the art. Also, the passivation layer 180 can be formed of SiO₂, borophosphosilicate glass (BPSG), tetra ethyl oxysilane (TEOS), SiN, or any other suitable material known in the art. The passivation layer 180 can be formed by any appropriate method known in the art, for example, electricity, CVD, or PVD. Also, the passivation layer 180 can be formed to have a thickness of about 0.3 μm to about 5 μm.

In a method for fabricating a semiconductor device according to an embodiment, a semiconductor substrate 100 including at least two holes for receiving devices can be provided. A plurality of devices (for example, 110, 120, 130, and 140) can be inserted into the holes of the semiconductor substrate 100. At least one connection electrode (for example, 171, 173, and 175) can be formed for electrically connecting the plurality of devices (for example, 110, 120, 130, and 140) A bonding pad portion 160 can be formed for signal connection between the plurality of devices (for example, 110, 120, 130, and 140) and an outside device.

In an embodiment, a passivation layer 180 ca n be formed on the connection electrodes (for example, 171, 173, and 175). The passivation layer 180 can be removed from a region where the bonding pad portion 160 has been formed.

According to embodiments of the present invention, individual devices can be connected using SbI, such that an integrated device can be more efficiently formed. Also, a heat sink can be easily formed and connected to an integrated device, which has been problematic in SiP-type stacked devices.

Moreover, embodiments of the present invention provide a simplified, more efficient fabricating process that allows for a high degree of integration of a semiconductor device.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A semiconductor device, comprising:
a semiconductor substrate including at least two holes;
at least two devices, wherein each device of the at least two devices is inserted into a hole of the at least two holes;
at least one connection electrode for electrically connecting the at least two devices; and
a bonding pad portion for signal connection between the at least two devices and an outside device.

2. The semiconductor device according to claim 1, wherein the semiconductor substrate comprises a silicon wafer.

3. The semiconductor device according to claim 1, wherein top surfaces of the at least two devices provided in the at least two holes of the semiconductor substrate have substantially the same height.

4. The semiconductor device according to claim 1, wherein each device of the at least two devices is an image sensor, a device having a capacitor cell, a device having an inductor cell, a central processing unit, static random access memory, dynamic random access memory, flash memory, a logic device, a power integrated circuit, a control integrated circuit, or a sensor chip.

5. The semiconductor device according to claim 1, further comprising a passivation layer on the at least one connection electrode.

6. The semiconductor device according to claim 5, wherein a portion of the passivation layer has been removed to expose the bonding pad portion.

7. The semiconductor device according to claim 5, wherein the passivation layer has a thickness of about 0.3 μm to about 5 μm.

8. The semiconductor device according to claim 5, wherein the passivation layer comprises SiO₂, borophosphosilicate glass (BPSG), tetra ethyl oxysilane (TEOS), or SiN.

9. The semiconductor device according to claim 1, wherein each connection electrode of the at least one connection electrode comprises Al, Ti/TiN/Al/Ti/TiN, Ti/Al/Ti/TiN, Ti/Al/TiN, Ti/TiN/Al/Ti, Ti/TiN/Al/TiN, Cu, or TaN/Cu/TaN.

10. The semiconductor device according to claim 1, wherein each connection electrode of the at least one connection electrode has a thickness of about 100 Å to about 10,000 Å.

11. A method for fabricating a semiconductor device, comprising:
providing a semiconductor substrate including at least two holes;
providing at least two devices;
inserting each device of the at least two devices into a hole of the at least two holes;
forming at least one connection electrode for electrically connecting the at least two devices; and
forming a bonding pad portion for signal connection between the at least two devices and an outside device.

12. The method according to claim 11, wherein the semiconductor substrate comprises a silicon wafer.

13. The method according to claim 11, wherein top surfaces of the at least two devices inserted into the at least two holes of the semiconductor substrate have substantially the same height in the semiconductor substrate.

14. The method according to claim 11, wherein each device of the at least two devices is an image sensor, a device having a capacitor cell, a device having an inductor cell, a central processing unit, static random access memory, dynamic random access memory, flash memory, a logic device, a power integrated circuit, a control integrated circuit, or a sensor chip.

15. The method according to claim 11, further comprising forming a passivation layer on the at least one connection electrode.

16. The method according to claim 15, further comprising removing a portion of the passivation layer to expose the bonding pad portion.

17. The method according to claim 15, wherein the passivation layer has a thickness of about 0.3 μm to about 5 μm.

18. The method according to claim 15, wherein the passivation layer comprises SiO₂, borophosphosilicate glass (BPSG), tetra ethyl oxysilane (TEOS), or SiN.

19. The method according to claim 11, wherein forming the at least one connection electrode comprises performing a chemical vapor deposition (CVD) or a physical vapor deposition (PVD).

20. The method according to claim 11, wherein each connection electrode of the at least one connection electrode comprises Al, Ti/TiN/Al/Ti/TiN, Ti/Al/Ti/TiN, Ti/Al/TiN, Ti/TiN/Al/Ti, Ti/TiN/Al/TiN, Cu, or TaN/Cu/TaN.
